(19) United States
(12) Patent Application Publication
(10) Pub. No.: US 2025/0301653 A1
(43) Pub. Date: Sep. 25, 2025

(54) SYSTEMS, DEVICES, AND METHODS FOR MANAGING SELECT GATES IN SEMICONDUCTOR DEVICES

(71) Applicant: Yangtze Memory Technologies Co., Ltd., Wuhan (CN)

(72) Inventors: Tian CHEN, Wuhan (CN); Kun ZHANG, Wuhan (CN); Yuhui HAN, Wuhan (CN); Wenxi ZHOU, Wuhan (CN); Zhiliang XIA, Wuhan (CN)

(21) Appl. No.: 18/778,433

(22) Filed: Jul. 19, 2024

Related U.S. Application Data
(63) Continuation of application No. PCT/CN2024/083472, filed on Mar. 25, 2024.

(51) Int. Cl. H10B 43/35; H10B 41/27; H10B 41/35; H10B 43/27

(52) U.S. Cl. CPC H10B 43/35; H10B 41/27; H10B 41/35; H10B 43/27

(57) ABSTRACT

Systems, devices, and methods for managing select gates in semiconductor devices are provided. In one aspect, a semiconductor device includes a first stack structure, a second stack structure, and a third stack structure. The first stack structure includes first conductive layers extending in a first region and a second region. The second stack structure is over the first stack structure along a first direction. The second stack structure includes interleaved second conductive layers and dielectric layers extending in the first region and the second region. The second stack structure includes a plurality of stairs in the second region. Each of the plurality of stairs includes a landing surface. The third stack structure is in a third region. A top surface of the third stack structure is at a level above the landing surface of an adjacent stair of the plurality of stairs along the first direction.

### CROSS-REFERENCE TO RELATED APPLICATIONS

This application is a continuation of International Application No. PCT/CN2024/083472, filed on Mar. 25, 2024, the disclosure of which is hereby incorporated by reference in its entirety.

### TECHNICAL FIELD

The present disclosure relates to semiconductor devices and fabrication processes for semiconductor devices.

### BACKGROUND

Semiconductor memory devices may be classified into non-volatile memory devices, such as flash memory devices, and volatile memory devices, such as dynamic random-access memory DRAMs. The semiconductor memory devices can have various structures to increase a density of memory cells and lines on a chip. A memory device normally includes a memory array of memory cells and control circuitries for facilitating operations of the memory array.

### SUMMARY

The present disclosure describes methods, devices, systems and techniques for managing select gates in three-dimensional (3D) semiconductor devices.

One aspect of the present disclosure features a semiconductor device, including a first stack structure, a second stack structure, and a third stack structure. The first stack structure includes first conductive layers extending in a first region and a second region. The second stack structure is over the first stack structure along a first direction. The second stack structure includes interleaved second conductive layers and dielectric layers extending in the first region and the second region. The second stack structure includes a plurality of stairs in the second region. Each of the plurality of stairs includes a landing surface. The third stack structure is in a third region. A top surface of the third stack structure is at a level above the landing surface of an adjacent stair of the plurality of stairs along the first direction.

In some implementations, the semiconductor device includes a plurality of contact structures in the third region. The plurality of contact structures extends into the third stack structure at different depths. A first contact structure of the plurality of contact structures includes a first vertical contact and a first interconnect line. The first interconnect line is in contact with the first vertical contact and a corresponding one of the first conductive layers.

In some implementations, edges of the second conductive layers and the dielectric layers in the second region are configured to define the plurality of stairs.

In some implementations, the semiconductor device includes first channel structures extending through the first stack structure and the second stack structure along the first direction in the first region.

In some implementations, the semiconductor device includes a plurality of select gate (SG) cut structures each extending through the second stack structure along a second direction. The second direction is perpendicular to the first direction. The SG cut structures are configured to separate each of the second conductive layers into a plurality of SG lines. A plurality of SG contact structures is each in contact with a respective SG line of the plurality of SG lines at a respective stair of the plurality of stairs in the second region.

In some implementations, the second region is between the first region and the third region along a second direction. The second direction is perpendicular to the first direction.

In some implementations, a SG cut structure of the SG cut structures partially extends into at least one of the first channel structures. A sidewall surface of the SG cut structure is in contact with a semiconductor channel layer of the at least one of the first channel structures.

In some implementations, the third region includes a dielectric portion and a conductive portion. The dielectric portion and the conductive portion are arranged in a third direction. The third direction is perpendicular to the first direction. The first conductive layers further extend in the conductive portion of the third region.

In some implementations, a SG line of the plurality of SG lines extends in the third region. A second contact structure of the plurality of contact structures includes a second vertical contact and a second interconnect line. The second interconnect line is in contact with the second vertical contact and the SG line.

In some implementations, the first conductive layers and the SG lines include tungsten (W).

Another aspect of the present disclosure features a method including: forming a stack structure including interleaved sacrificial layers and first dielectric layers in a first region, a second region and a third region. A plurality of stairs in the stack structure are formed in the second region. Each of the plurality of stair includes a sacrificial layer of the sacrificial layers. The plurality of stairs is descending along a first direction. Contact structures are formed which extend into the stack structure at different depths in the third region. The sacrificial layers are replaced with conductive layers in the first region and the second region. One or more select gate (SG) cut structures are formed. Each SG cut structure extends through at least one of the conductive layers of the stack structure in the first region and the second region. The one or more SG cut structures are configured to separate the at least one of the conductive layers into SG lines.

In some implementations, a plurality of SG contact structures is formed. Each SG contact structure is in contact with a respective SG line of the SG lines at a respective stair of the plurality of stairs in the second region.

In some implementations, a plurality of first channel structures is formed, which extends through the stack structure along a second direction in the first region. A plurality of dummy channel structures extends through the plurality of stairs along the second direction in the second region. The second direction is perpendicular to the first direction.

In some implementations, the sacrificial layers are replaced with the conductive layers in a conductive portion of the third region.

In some implementations, forming the contact structures includes forming a first vertical contact in a dielectric portion of the third region. The dielectric portion and the conductive portion are arranged in a third direction. The third direction is perpendicular to the first direction.

In some implementations, a part of a sacrificial layer of the sacrificial layers is replaced with an interconnect line in the dielectric portion of third region. The interconnect line is in contact with the first vertical contact and a corresponding one of the conductive layers.

In some implementations, a part of a sacrificial layer of the sacrificial layers is replaced with an interconnect line in the dielectric portion of third region. The interconnect line is in contact with the first vertical contact and a corresponding one of the SG lines.

In some implementations, one of the one or more SG cut structures partially extends into at least one of the first channel structures. A sidewall surface of the SG cut structure is in contact with a semiconductor channel layer of the at least one of the first channel structures.

In some implementations, forming the plurality of first channel structures includes forming a blocking layer, a charge trapping layer, a dielectric layer and a channel layer arranged radially in each of the plurality of first channel structures.

Another aspect of the present disclosure features a system including: a memory device configured to store data and a memory controller electrically connected to the memory device and configured to operate the memory device. The memory device includes a first stack structure having first conductive layers extending in a first region and a second region. A second stack structure is over the first stack structure along a first direction. The second stack structure includes interleaved second conductive layers and dielectric layers extending in the first region and the second region. The second stack structure includes a plurality of stairs in the second region. Each of the plurality of stairs includes a landing surface. A third stack structure is in a third region. A top surface of the third stack structure is at a level above the landing surface of an adjacent stair of the plurality of stairs along the first direction.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1A illustrates a cross-sectional view of an example semiconductor device.

FIG. 1B illustrates a cross-sectional view of example channel structures and select gate cut structures of the example semiconductor device.

FIG. 2A illustrates a top view of the example semiconductor device with an example second region.

FIG. 2B illustrates a top view of the example semiconductor device with another example second region.

FIGS. 3A-3B illustrate cross-section views of an example third stack structure in a third region of the example semiconductor device.

FIGS. 4A-4D illustrate cross-section views of the example semiconductor device at various stages of a fabrication process.

FIG. 5 is a flow chart for an example process to form the example semiconductor device.

FIG. 6 illustrates a block diagram of a system having one or more semiconductor devices.

It is to be understood that the various exemplary implementations shown in the figures are merely illustrative representations and are not necessarily drawn to scale.

### DETAILED DESCRIPTION

In some 3D memory devices, such as 3D NAND memory devices, a stack of gate electrodes may be arranged over a substrate, with a plurality of semiconductor channels through and intersecting word lines, into the implanted substrate. The bottom/lower gate electrode or electrodes function as source select gate lines, which are also called bottom select gates (BSG) in some cases. The top/upper gate electrode or electrodes function as drain select gate lines, which are also called top select gates (TSG) in some cases. The gate electrodes between the top/upper select gate electrodes and the bottom/lower gate electrodes function as word lines (WL). The intersection of a word line and a semiconductor channel forms a memory cell. The TSG can select specific memory cells or memory strings for read, program or erase operations within a NAND flash memory array under control of peripheral circuitries. The TSG can be coupled to the peripheral circuitries through select gate contact structures. The select gate contact structures can be made of conductive materials.

Implementations of the present disclosure provide semiconductor devices and methods to form such semiconductor devices. In some implementations, a semiconductor device includes a first stack structure, a second stack structure, and a third stack structure. The first stack structure includes first conductive layers extending in a first region and a second region. The second stack structure is over the first stack structure along a first direction. The second stack structure includes interleaved second conductive layers and dielectric layers extending in the first region and the second region. The second stack structure includes a plurality of stairs in the second region. Each of the plurality of stairs includes a landing surface. The third stack structure is in a third region. A top surface of the third stack structure is at a level above the landing surface of an adjacent stair of the plurality of stairs along the first direction.

Implementations of the present disclosure can provide one or more of the following technical advantages and/or benefits. First, TSG can have multiple SG conductive layers. Each SG conductive layer can extend along a lateral direction from a memory array region to a dummy region surrounding the memory array region. A staircase structure can be formed for the multiple SG conductive layers in the dummy region with SG contact structures situated on a landing surface of the respective stairs. As the staircase structure can be formed in the dummy region, it doesn't demand extra space. In addition, with this staircase structure, a polysilicon deck is not required in TSG formation, as TSGs can share the same material as the word lines. This streamlines the manufacturing process, reducing complexity and cost. For example, the TSG and memory cells can be formed together by forming a stack structure having interleaved sacrificial layers and dielectric layers and then replacing the sacrificial layers with a conductive material, e.g., tungsten (W). These techniques reduce the requirement for additional polysilicon deposition steps. Further, the techniques described in the present disclosure are compatible with the process for forming word lines contact structures that can achieve the word line pick-up/fan-out functions without using staircase structures. In particular, the replacement of the conductive material, e.g., tungsten (W), for the memory cells and/or TSGs can occur either before or after forming the word lines contact structures, providing flexibility to tailor the manufacturing process as needed. Additionally, this staircase configuration decreases the risk of bending in SG gate layers, thereby enhancing manufacturing stability and reliability.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

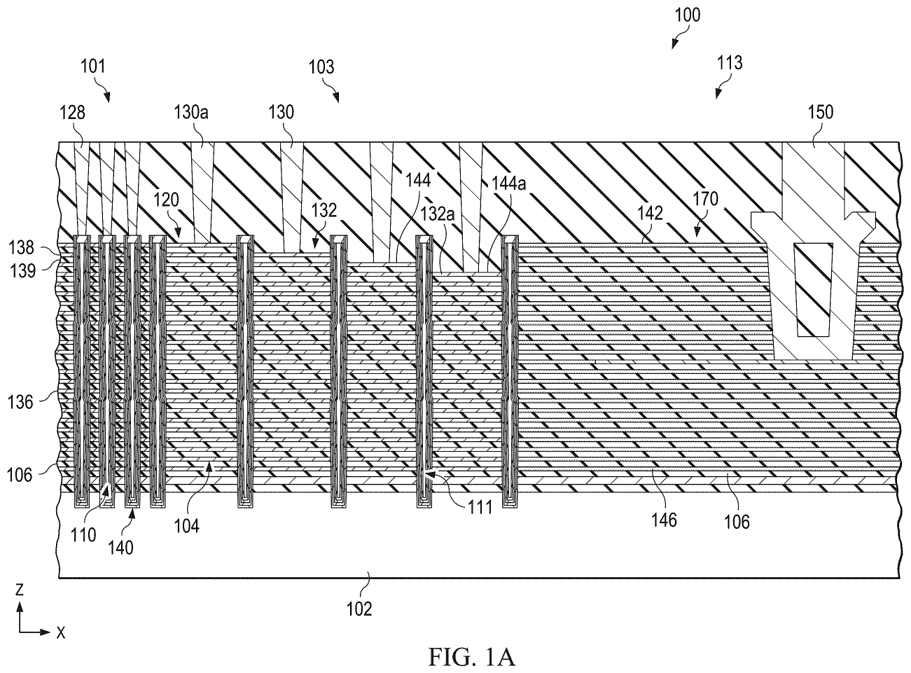

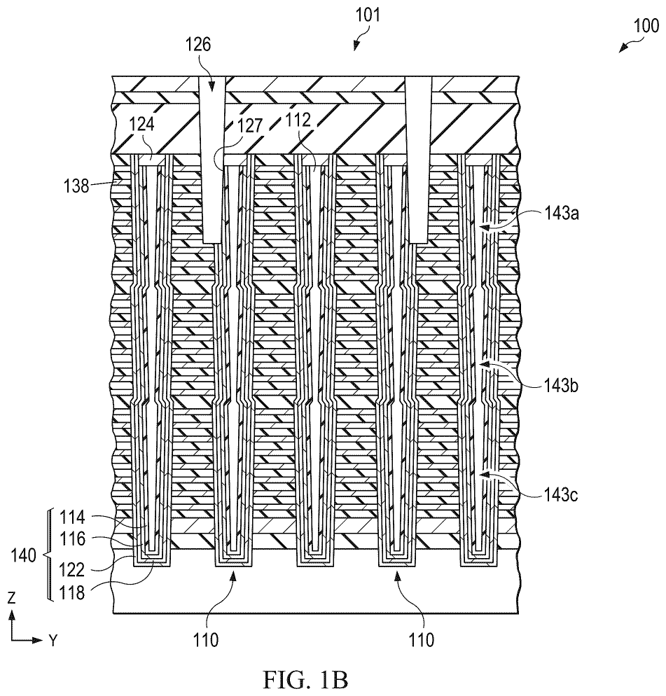

FIG. 1A illustrates a side view of a cross-section of an example 3D semiconductor device 100. A 3D memory device 100 can include a substrate 102, which is a doped semiconductor layer and can include silicon (e.g., single crystalline silicon), silicon germanium (SiGe), gallium arsenide (GaAs), germanium (Ge), silicon on insulator (SOI), germanium on insulator (GOI), or any other suitable materials. In some implementations, substrate 102 is a thinned substrate (e.g., a semiconductor layer), which was thinned by grinding, etching, chemical mechanical polishing (CMP), or any combination thereof. Substrate 102 of 3D memory device 100 includes two surfaces (e.g., a top surface and a bottom surface) extending laterally in the x-direction (i.e., the lateral direction). As used herein, whether one component (e.g., a layer or a device) is “on,” “above,” or “below” another component (e.g., a layer or a device) of a 3D memory device (e.g., 3D memory device 100) is determined relative to the substrate of the 3D memory device (e.g., substrate 102) in the z-direction (i.e., the vertical direction) when the substrate is positioned in the lowest plane of the 3D memory device in the z-direction.

In some implementations, 3D memory device 100 is a NAND Flash memory device in which memory cells are provided in the form of an array of NAND memory strings each extending vertically above substrate 102.

As shown in FIG. 1A, the 3D memory device 100 can include three regions, a first region 101, a second region 103 and a third region 113. In some implementations, the second region 103 is between the first region 101 and the third region 113 along the x direction. In some implementations, the first region 101, the second region 103 and the third region 113 can be arranged along different directions. For example, the second region 103 can be adjacent to the first region 101 along x direction, while the third region 113 can be adjacent to the first region 101 along y direction.

The 3D memory device 100 can include a first stack structure 104. In some implementations, the first stack structure 104 has interleaved first conductive layers 136 and first dielectric layer 106 extending in the first region 101 and the second region 103. The stacked first conductive layer 136/first dielectric layer 106 pairs can be also referred to as a memory stack in this disclosure. The first region 101 can be also referred as the memory array region 101 in this disclosure. The second region 103 can be also referred as the staircase region 103 in this disclosure. The first conductive layers 136 can be also referred as the gate lines 136 or the word lines 136 in this disclosure.

In some implementations, each gate line 136 in first stack structure 104 (e.g., a memory stack) functions as a gate conductor of memory cells in the NAND memory string. Gate lines 136 can extend laterally coupling a plurality of memory cells. The gate lines 136 can include conductive materials including, but not limited to, tungsten (W), cobalt (Co), copper (Cu), aluminum (Al), polysilicon, doped silicon, silicides, or any combination thereof. First dielectric layers 106 can include dielectric materials including, but not limited to, silicon oxide, silicon nitride, silicon oxynitride, or any combination thereof.

The 3D memory device 100 can further include a second stack structure 120 which is on top of the first stack structure 104 along a first direction, e.g., the Z direction. The second stack structure 120 can include interleaved second conductive layers 138 and dielectric layers 139 extending in the first region 101 and the second region 103. In some implementations, the second stack structure 120 has 2-10 layers of the second conductive layers 138. The second stack structure 120 can be utilized as top select gates (SG) to help control the operation of the NAND flash memory cell during read, program, and/or erase operations. The second conductive layers 138 can include the same material, e.g., Tungsten (W), as the first conductive layers 136. The dielectric layers 139 include the same material, e.g., silicon oxide, as the first dielectric layers 106. The dielectric layers 139 can also be referred as the second dielectric layers 139 in this disclosure.

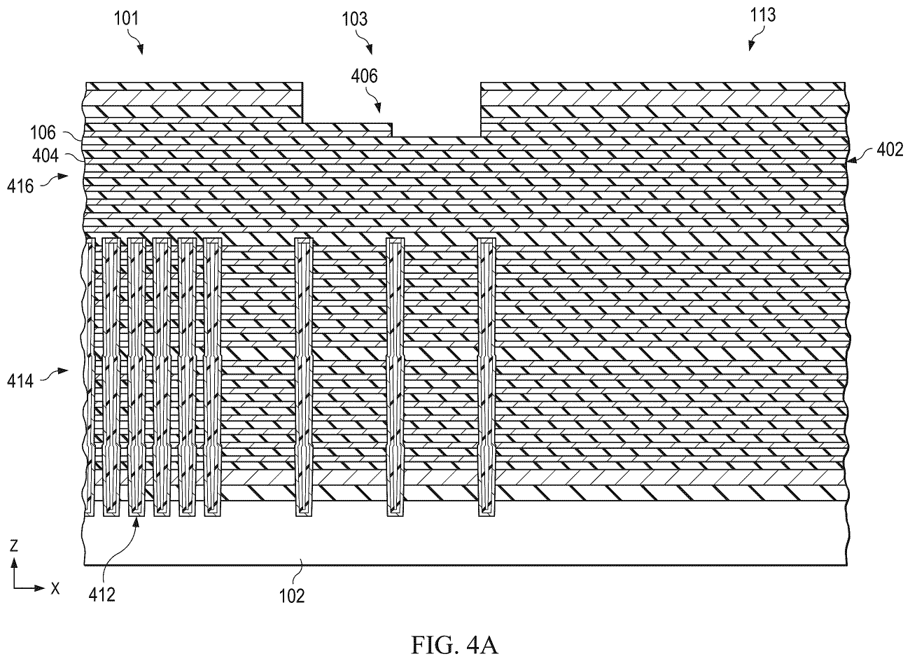

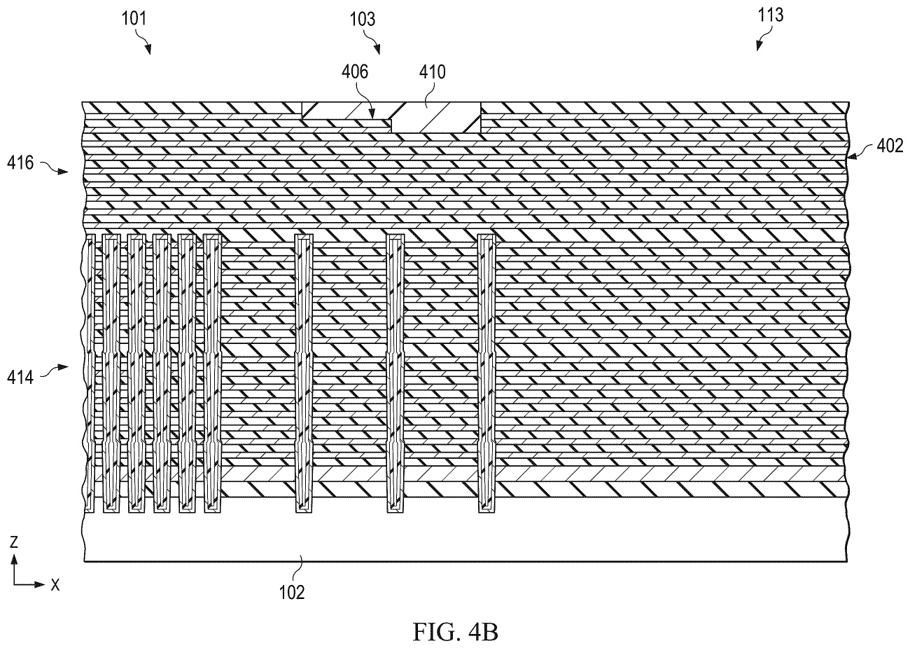

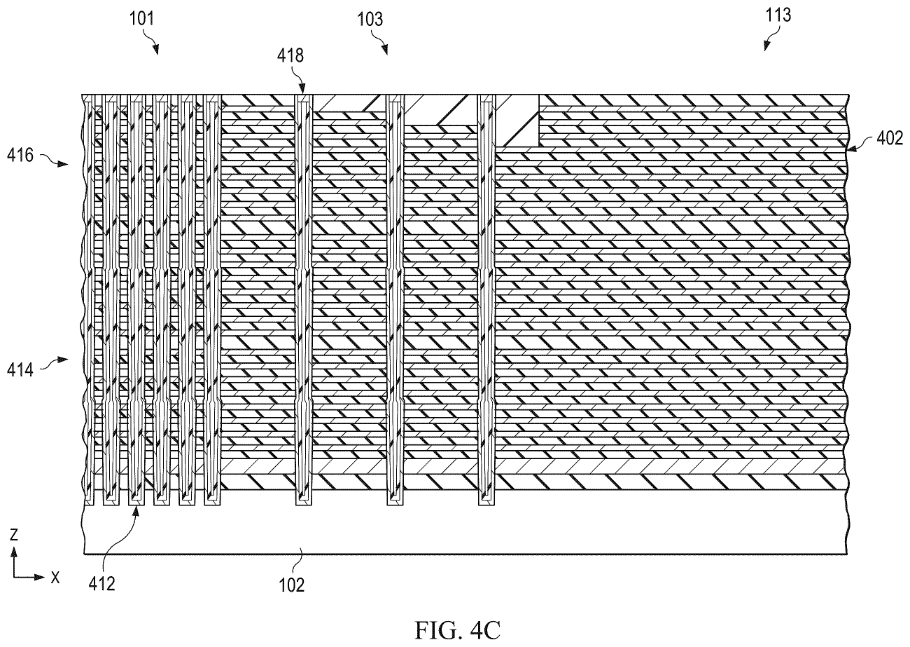

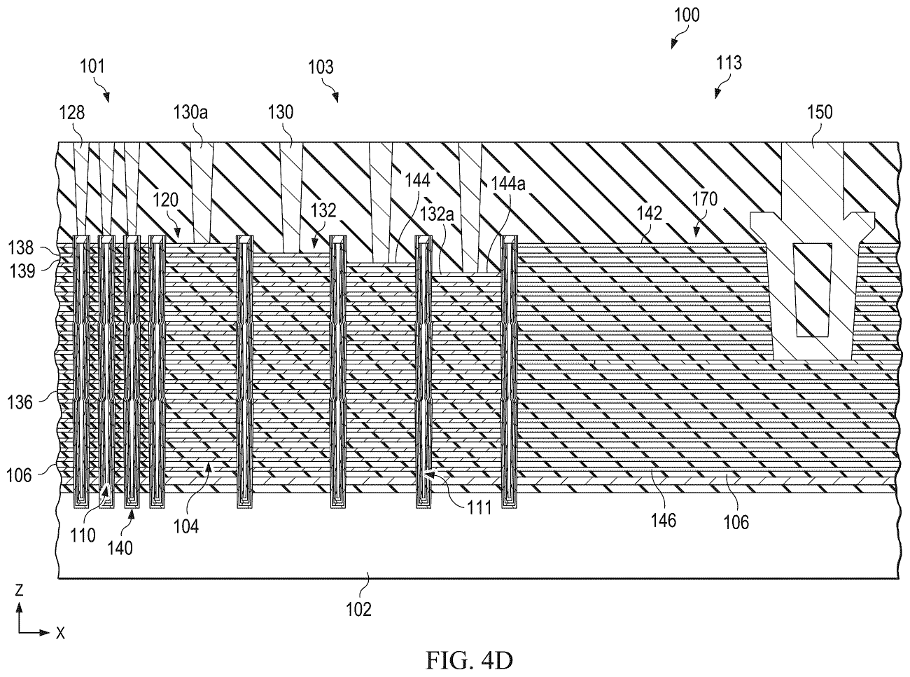

Edges of the second conductive layers 138 and the second dielectric layers 139 can define a plurality of stairs 132 in the second region 103 (staircase region 103), as illustrated in FIG. 1A. The process steps to form stairs 132 are described with further details below in FIGS. 4A-4C. Each second conductive layer 138 can vary in length along the x-direction, creating a staircase-like pattern. Each stair 132 can include two layers, the second dielectric layer 139 and the second conductive layer 138 on top of the second dielectric layer 139. Each stair 132 can include a landing surface 144. The landing surface 144 can be the top surface of the second conductive layer 138 for each stair 132 that is not covered by the preceding stair 132. In some implementations, the number of stairs 132 is equal to the number of second conductive layers 138 of the second stack structure 120, such that each second conductive layer 138 is associated with one stair 132. In some implementations, the stairs 132 are descending along the x-direction. The second conductive layers 138 can also be referred as SG layers 138 in this disclosure.

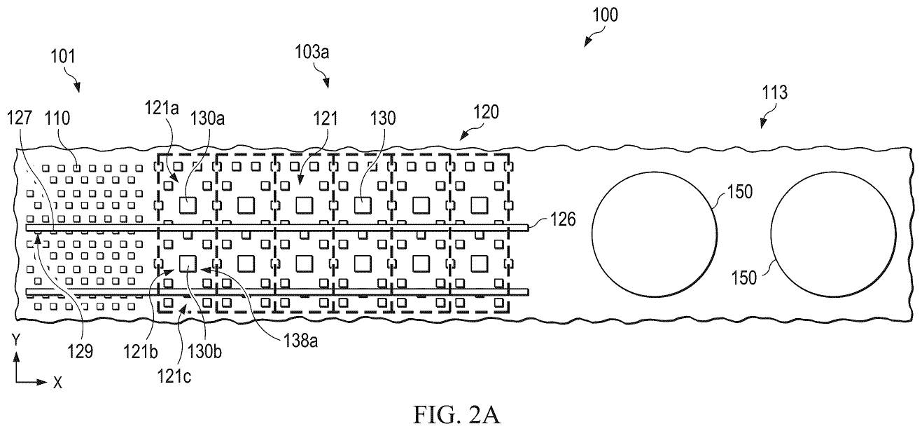

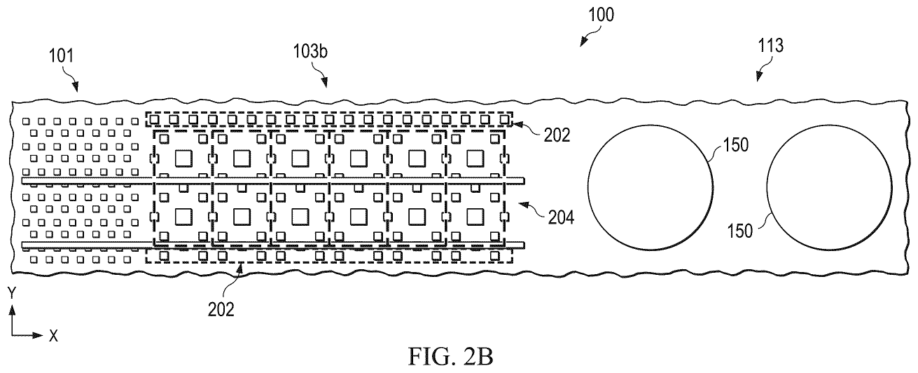

FIG. 2A illustrates a top view of an example semiconductor device 100 with an example second region 103a. The semiconductor device 100 can include at least one select gate (SG) cut structure 126. Each SG cut structure 126 can extend through the second stack structure 120 along a second direction, e.g., x-direction. The SG cut structures 126 can be configured to separate each of the second conductive layers 138 (SG layers 138) into multiple SG lines 121. For example, the first SG layer 138a can be separated into three SG lines, 121a, 121b, 121c by the two SG cut structures 126 as illustrated in FIG. 2A. Each SG line 121 can extend in the first region 101 (memory array region 101) and at least partially in the second region 103 (staircase region 103) along the x-direction. Each SG line 121 can be a select gate line for corresponding memory string. A gate-selective voltage can be applied on the select gate line for selecting the respective string in operations. SG cut structure 126 can be used for electrically insulating the SG lines 121 between two adjacent memory strings. In some implementations, SG cut structures 126 are formed by a dielectric material, including, but not limited to, silicon oxide, silicon nitride, silicon oxynitride, or any combination thereof. The SG lines 121 can have the same material, e.g., tungsten (W), as the first conductive layers 136.

The semiconductor device 100 can include at least one SG contact structure 130. Each SG contact structure 130 can be in contact with a respective SG line 121 of at a respective stair 132 in the second region 103. For example, as illustrated in FIG. 2A, a first SG contact structure 130a can be in contact with the respective SG line 121a. More specifically, the first SG contact structure 130a can be in contact with the landing surface 144 of the respective first SG line 121a. As noted above, the landing surface 144 can be the top surface of the corresponding second conductive layer 138. Therefore, the SG contact structure 130 can be electrically connected to the corresponding second conductive layer 138 of the second stack structure 120. Likewise, a second SG contact structure 130b can be in contact with the landing surface 144 of the respective second SG line 121b. It is understood that during formation process, the SG contact structures 130 can partially extend into the second conductive layer 138 of the corresponding SG line 121. The SG line 121 can be coupled to other circuitries or devices through the SG contact structures 130. In some implementations, the SG contact structures 130 have conductive material, including, but not limited to, W, Co, Cu, Al, TiN, TaN, polysilicon, or any combination thereof.

Referring back to FIG. 1A, the semiconductor device 100 can further include first channel structures 110 extending through the first stack structure 104 and the second stack structure 120 along the first direction, e.g., z direction, in the first region 101. FIG. 1B illustrates a cross-sectional view of example channel structures and select gate cut structures of the example semiconductor device 100. The first channel structures 110 can include a channel hole or a channel trench with a layered structure 140 formed on sidewalls of the channel hole or trench. In some implementations, the remaining space of first channel structures 110 can be partially or fully filled with a filling layer 112 including dielectric materials, such as silicon oxide.

In some implementations, the layered structure 140 includes a blocking layer 122, a charge trapping layer 118 (also called storage layer in some cases), a dielectric layer 116 (also called a tunneling layer in some cases), and a semiconductor channel layer 114. As shown in FIG. 1B, the semiconductor channel layer 114 is in contact with and laterally surrounded by the dielectric layer 116. The dielectric layer 116 is in contact with and laterally surrounded by the charge trapping layer 118. The charge trapping layer 118 is in contact with and laterally surrounded by the blocking layer 122. In other words, the filling layer 112, semiconductor channel layer 114, dielectric layer 116, charge trapping layer 118, and blocking layer 122 can be arranged radially from the center toward the outer surface of the channel trench in this order. The semiconductor channel layer 114 can include doped polysilicon or silicon germanium (SiGe). The dopants can be N type dopants (e.g., Phosphorus (P) or Arsenic (As)) or P type dopants (e.g., Boron (B) or Gallium (Ga)) at a desired doping level. The dielectric layer 116 can include silicon oxide, silicon oxynitride, or any combination thereof. The charge trapping layer 118 can include silicon nitride, silicon oxynitride, silicon, or any combination thereof. The blocking layer 122 can include silicon oxide, silicon oxynitride, high dielectric constant (high-k) dielectrics, or any combination thereof. In one example, the layer structure 140 includes silicon oxide/silicon oxynitride (or silicon nitride)/silicon oxide/polysilicon (ONOP), for the blocking layer 122, the charge trapping layer 118, the dielectric layer 116, and the semiconductor channel layer 114 respectively.

The first channel structure 110 can have a cylinder shape (e.g., a pillar shape). In some implementations, first channel structure 110 can be formed by stacking more than one cylinder structure. As shown in FIG. 1B, three cylinder structures 143a, 143b, 143c, are stacked together to form a first channel structure 110. It is understood that the first channel structures 110 can have other shapes (e.g., elliptical cylinder or irregular shape).

In some implementations, as illustrated in FIG. 1B, first channel structure 110 further includes a channel plug 124 in an upper portion (e.g., at the upper end) of first channel structure 110, which can be stacked over the layered structure 140 along the z-direction. Channel plug 124 can be in contact with the upper end of semiconductor channel layer 114 of the layered structure 140. In some implementations, the channel plug material can include, but not limited to, TiN, TaN, Al, W, Cu, doped-polysilicon, silicides, or any combination thereof. By covering the upper end of first channel structure 110 during the fabrication of 3D memory device 100, channel plug 124 can function as an etch stop layer to prevent etching of dielectrics filled in first channel structure 110, such as silicon oxide and silicon nitride. In some implementations, channel plug 124 also functions as the drain of the NAND memory string.

A sidewall surface 127 of the SG cut structure 126 can be in contact with the semiconductor channel layer 114 of the first channel structure 110. In other words, the SG cut structure 126 partially extends into the first channel structure 110 and/or the channel plug 124. By forming the second stack structure 120 around the layered structure 140, a better Vt adjustment for select gate can be achieved with a floating gate structure (e.g., ONOP). In some implementations, each SG cut structure 126 is in contact with a corresponding row of the channel structures 110. For example, as illustrated in FIG. 2A, one of the SG cut structures 126 can be in contact with the corresponding row 129 of the channel structures 110.

In some implementations, as the select cut structures 126 only partially extend into the corresponding first channel structures 110 and are in contact with the semiconductor channel layers 114, the first channel structures 110 can still be functional channels in which memory cells are formed. Consequently, the requirements for dummy channel structures in the first region 101 can be reduced, allowing for an increased density of memory strings.

Returning to FIG. 1A, the semiconductor device 100 can also include a plurality of dummy channel structures 111 extending through the first stack structure 104 and the second stack structure 120 along the first direction, e.g., z direction, in the second region 103 (staircase region 103). Adjacent dummy channel structures 111 can be arranged along x direction and/or y direction. The dummy channel structure 111 can have a structure substantially similar to the first channel structure 110. In some implementations, the dummy channel structures 111 have a lower array density compared to the first channel structures 110. For examples, the pitch between adjacent dummy channel structures 111 can be higher than that of the first channel structures 110. The dummy channel structures 111 can be utilized to provide mechanical support for both the first stack structure 104 and the second stack structure 120 to reduce the risk of bending, rather than functioning as active memory cells or strings.

In some implementations, the semiconductor device 100 includes a channel contact 128 coupled to the respective first channel structures 110. The channel contact 128 can comprise conductive materials including, but not limited to, tungsten (W), cobalt (Co), copper (Cu), aluminum (Al), polysilicon, doped silicon, silicides, or any combination thereof. The channel contact 128 can be configured to connect memory cells to bit lines, back end of line (BEOL) metal routings and/or peripheral circuitry.

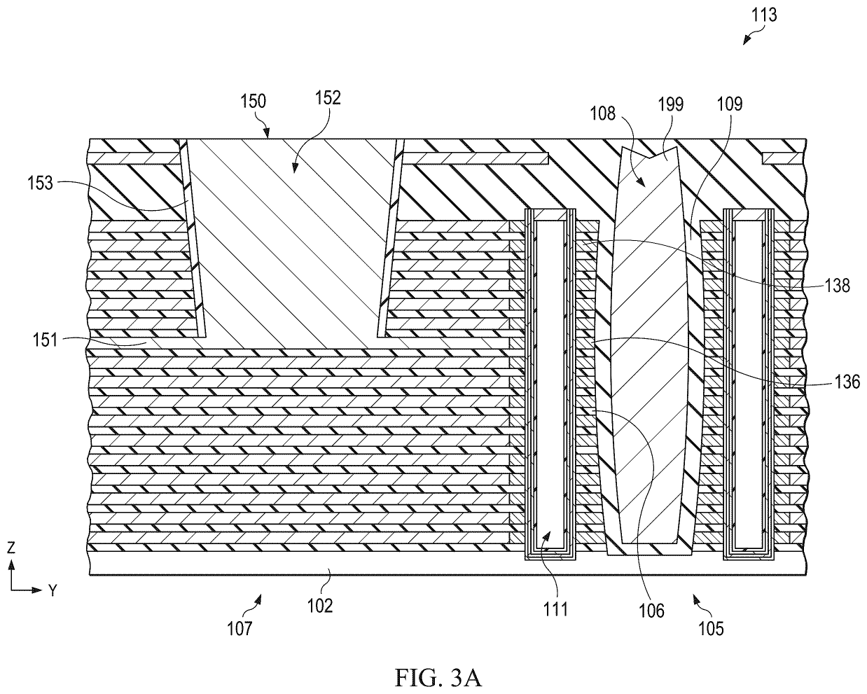

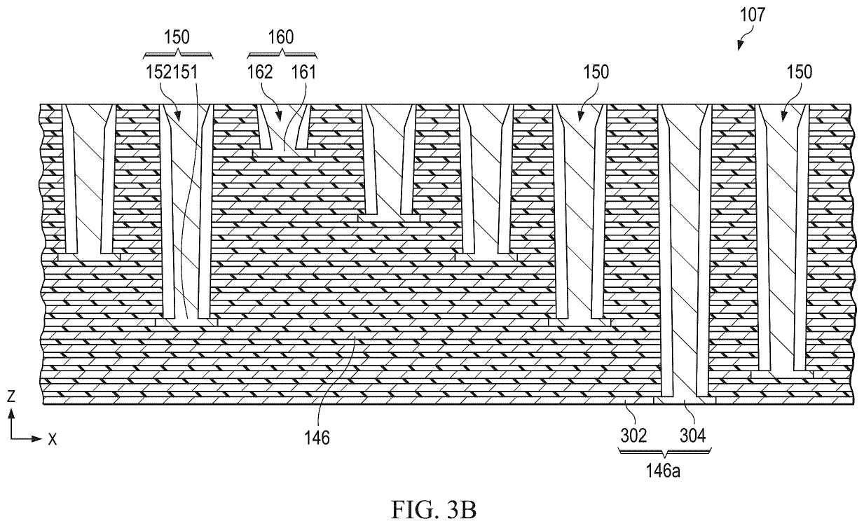

The semiconductor device 100 can further include a third stack structure 170 in a third region 113. The third stack structure 170 can include first dielectric layers 106, e.g., silicon oxide, interleaved material layers 146. As described below with further details in FIGS. 3A-3B, each of the material layers 146 can include a dielectric material, e.g., silicon nitride, in a first portion 302, and a conductive material, e.g., W, in a second portion 304. The conductive material, e.g., W, in the second portion 304 can form the interconnect line 151 of the contact structure 150. The lateral dimensions and/or positions of the second portions 304 can differ across different material layers 146. In some implementations, the second region 103 is between the first region 101 and the third region 113 along the second direction, e.g., the x direction, as illustrated in FIG. 1A.

In some implementations, the top surface of the third stack structure 170 is at a level above the landing surface 144 of an adjacent stair 132a along the first direction, e.g., z direction. For example, as illustrated in FIG. 1A, the top surface 142 of the third stack structure 170 can be higher than the landing surface 144a of the adjacent stair 132a along z direction, as the stairs 132 are descending along the positive x direction. In some implementations, the third region is not adjacent to the second region or the stairs 132 are ascending along the positive x direction. The adjacent stair 132a can refer to the lowest stair 132 in the staircase region 102 in the positive z direction. In other words, the top surface 142 of the third stack structure 170 can be higher than the landing surface 144a of the lowest stair 132, e.g., the adjacent stair 132a, along z direction.

FIGS. 3A-3B illustrate cross-section views of the third stack structure 170 in the third region 113 of the example semiconductor device 100. More specifically, FIG. 3A illustrates a cross-section view in Y-Z plane, while FIG. 3B illustrates a cross-section view in X-Z plane and/or Y-Z plane.

As illustrated in FIG. 3A, the third region 113 can include a dielectric portion 107 and a conductive portion 105. The dielectric portion 107 and the conductive portion 105 can be arranged in a third direction, e.g., the y direction. The first conductive layers 136 can extend from the first region 101 into the conductive portion 105 of the third region 113 along the x direction.

The semiconductor device 100 can include a plurality of contact structures in the third region 113. The contact structures can be used for word line pick-up/fan-out in the third region 113 and/or SG lines pick-up/fan-out in the third region 113. The contact structures 150 used for word line pick-up/fan-out in the third region 113 can be referred as the first contact structures 150 in this disclosure. The contact structures used for SG lines 121 pick-up/fan-out in the third region 113 can be referred as the second contact structures 160 in this disclosure. It is understood that, although for various applications, the first contact structures 150 utilized for word line pick-up/fan-out can share identical or substantially similar structures with the second contact structures 160 used for SG lines pick-up/fan-out. The contact structures in the third region 113 can be referred generally as the contact structures 150, 160 or individually as the contact structure 150, 160 in this disclosure.

As shown in FIG. 3A, each contact structure 150, 160 can include an interconnect line 151 and a vertical contact 152. The vertical contact 152 can be in contact with the interconnect line 151. The interconnect line 151 can extend laterally in the y-direction (the bit line direction) to be in contact with a corresponding first conductive layer 136 (word line 136) in the conductive portion 105 at the same level of third stack structure 170. Since interconnect line 151 is in contact with vertical contact 151 of contact structure 150, each first contact structure 150 is electrically connected to corresponding first conductive layer 136 (word line 136) across conductive portion 105 in third region 113. In other words, first contact structures 150 can extend vertically through third stack structure 170 at different depths to be electrically connected to the word lines 136 at different levels, respectively, to achieve word line pick-up/fan-out, as described below with further details in FIG. 3B.

In some implementations, as shown in FIG. 3A, the vertical contact 152 includes a conductive material surrounded by a spacer layer 153. The interconnect line 151 can have the same conductive material as the vertical contact 152. In some implementations, the conductive material includes, without limitation to, W, Co, Cu, Al, TiN, TaN, polysilicon, or any combination thereof. The spacer layer 153 includes, without limitation to, silicon oxide, silicon nitride, silicon oxynitride, or any combination thereof. In some implementations, vertical contact 152 and interconnect line 151 include TiN/W, and the spacer layer 153 includes silicon oxide.

As illustrated in FIG. 3A, the 3D memory device 100 can include one or more dummy channel structures 111 in the conductive portion 105 of third region 113. Each dummy channel structure 111 can extend vertically through interleaved first conductive layers 136 and first dielectric layers 106 into the substrate 102. 3D memory device 100 can further include one or more slit structures 108 extending along the x direction across the first region 101, the second region 103 and the third region 113. Each slit structure 108 can extend vertically through interleaved first conductive layers 136 and first dielectric layers 106 into substrate 102 as well. As shown in FIG. 3A, slit structure 108 can include a slit spacer 109 that separate first conductive layers 136 (gate lines) between adjacent memory blocks. In some implementations, slit structure 108 is an insulating structure that does not include any contact therein (i.e., not functioning as the source contact) and thus, does not introduce parasitic capacitance and leakage current with first conductive layers 136 (gate lines). In some implementations, slit structure 108 is a front-side source contact further including an inner conductive portion 199 (e.g., including W, polysilicon, and/or TiN) circumscribed by slit spacer 109.

In some implementations, the first conductive layers 136 extend from the first region 101 into the third region 113 through edge regions of the second region 103. FIG. 2B illustrates a top view of the example semiconductor device 100 with another example second region 103b. As shown, the second region 103b can include one or more edge regions 202 and a middle region 204. The staircase configurations of the second stack structure 120 can be formed in the middle region 204 of the second region 103. The first conductive layers 136 can extend into the edge regions 202 of the second region 103 and further into the third region 113. Therefore, the first conductive layers 136 (word lines 136) can be coupled to structures or devices, e.g., the first contact structures 150, in the third region 113. In some implementations, the SG lines 121 extend into the edge regions 202 of the second region 103 and further into the third region 113. Thus, the SG lines 121 can be coupled to structures or devices, e.g., the second contact structures 160, in the third region 113, as described with further details in FIG. 3B below.

As illustrated in FIG. 3B, the contact structures 150, 160 extend vertically into the third stack structure 170 in the dielectric portion 107 of third region 113 at different depths in the z-direction, according to some implementations. The top surfaces of different first contact structures 150 can be flush with one another, while the bottom surfaces of different first contact structures 150 can extend to different levels, for example, different material layers 146 of the third stack structure 170.

Each of the material layers 146 can include a dielectric material in a first portion 302 and a conductive material in a second portion 304. For instance, the bottom material layer 146a can have the first portion 302 which includes a dielectric material, e.g., silicon nitride, and a second portion 304 which includes a conductive material, e.g., W, for forming the interconnect line 151. As illustrated in FIG. 3A, the second portion 304 or the interconnect lines 151 can extend along the y direction to connect to a corresponding first conductive layer 136 in the conductive portion 105 of the third region 113.

In some implementations, a SG line 121 extends in the conductive portion 105 of the third region 113. As noted above, the first contact structures 160 can be utilized for SG gate lines 121 pick-up/fan-out. Both contact structures 150, 160 can be in the dielectric portion 107 of the third region 113. As illustrated in FIG. 3B, the second contact structure 160 can include a second vertical contact 162 and a second interconnect line 161. The second interconnect line 161 is in contact with the second vertical contact 162 and the corresponding SG line 121. It is understood that the second vertical contact 162 can have the same as or substantial similar structures/materials as the first vertical contact 152, and the second interconnect line 161 can have the same as or substantial similar structures/materials as the first interconnect line 151.

In some implementations, the SG lines 121 are connected to other devices or circuitries through the SG contact structures 130 in the staircase region 103, as described above in FIG. 1A. In some implementations, the SG lines 121 are connected to other devices or circuitries through both the SG contact structures 130 in the staircase region 103 and the second contact structures 160 in the third region 113. In some implementations, some of the SG lines 121 are connected to other devices or circuitries through the SG contact structures 130 in the staircase region 103, while other SG lines 121 are connected to other devices or circuitries through the second contact structures 160 in the third region 113. In some implementations, the contact structures in the third region only include the first contact structures 150 for word line pick-up/fan-out. In some implementations, the contact structures in the third region include both the first contact structures 150 for word line pick-up/fan-out and the second contact structures 160 for SG lines pick-up/fan-out.

FIGS. 4A-4D illustrate cross-section views of the example semiconductor device 100 at various stages of a fabrication process. As illustrated in FIG. 4A, a stack structure 402 can be formed on the substrate in the first region 101, the second region 103 and the third region 113. A stack structure 402 can include interleaved sacrificial layer 404 and insulating layer, e.g., first dielectric layer 106. The sacrificial layer 404 can be configured to be replaced with a conductive material to form gate lines 136 at least in the first region 101 at a later stage of the process as described below in FIG. 4C. First dielectric layers 106 can include dielectric materials including, but not limited to, silicon oxide, silicon nitride, silicon oxynitride, or any combination thereof. Sacrificial layers 404 can also include dielectric materials including, but not limited to, silicon oxide, silicon nitride, silicon oxynitride, or any combination thereof. Sacrificial layer 404 can include a different material than the first dielectric layer 106 such that it can be selectively removed and replaced with a conductive material at a later processing stage. For example, the sacrificial layer can include silicon nitride, while the first dielectric layer 106 can include silicon oxide. The sacrificial layer 404 and/or the first dielectric layer 106 can be deposited using one or more thin film deposition techniques, including, but not limited to, chemical vapor deposition (CVD), physical vapor deposition (PVD), atomic layer deposition (ALD), sputtering, or any combination thereof.

In some implementations, as shown in FIG. 4A, one or more initial channel structures 412 can be formed which extend through the bottom portion 414 of the stack structure 402. The bottom portion 414 of the stack structure 402 in the first region 101 and the second region 103 can be utilized to form the first stack structure 104, while the top portion 416 of the stack structure 402 in the first region 101 and the second region 103 can be utilized to form the second stack structure 120. The initial channel structures 412 can extend partially into the substrate 102. In some implementations, the initial channel structures 412 have a cylinder shape. Because of etching process, the cylinder can have a larger top end compared to the bottom end. In some implementations, the initial channel structures 412 can be formed by stacking more than one cylinder structures, as shown in FIG. 1B. In some implementations, the initial channel structures 412 are not formed at this stage; rather, they can be formed at a suitable subsequent stage.

In some implementations, the initial channel structures 412 include the layered structure 140 (not shown in this figure). In some implementations, the layered structure 140 includes a filling layer 112, semiconductor channel layer 114, dielectric layer 116, charge trapping layer 118, and blocking layer 122, which are arranged radially from the center toward the outer surface of the initial channel structures 412 in this order, as shown in FIG. 4B. In some implementations, the layered structure 140 includes silicon oxide/silicon oxynitride (or silicon nitride)/silicon oxide/polysilicon (ONOP), for the blocking layer 122, the charge trapping layer 118, the dielectric layer 116, and the semiconductor channel layer 114 respectively.

A subsequent etching can be performed to form at least one initial stair 406 in the second region 103 as illustrated in FIG. 4A. At this stage, each of the initial stairs 406 can include a sacrificial layer 404 and a first dielectric layer 106. In some implementations, the first dielectric layer 106 is on top of the sacrificial layer 404 for initial stair 406. In some implementations, the first dielectric layer 106 is below the sacrificial layer 404 for initial stair 406.

In some implementations, the initial stairs 406 are descending along the x direction. The etching of stairs can involve one or more dry etching and/or wet etching techniques, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H₂SO₄/H₂O₂), or any combination thereof.

As illustrated in FIG. 4B, a filling dielectric material 410, e.g., the silicon oxide, can be deposited above the initial stairs 406 in the second region 103 (staircase region 103). A polishing process can be subsequently employed to planarize and smooth the surfaces of stacked structures in all three regions. The filling dielectric material 410 can have the same material as the first dielectric material 106. The filling dielectric material 410 can be deposited using one or more thin film deposition techniques, including, but not limited to, chemical vapor deposition (CVD), physical vapor deposition (PVD), atomic layer deposition (ALD), sputtering, or any combination thereof. The polishing process can include mechanical thinning (e.g., grinding, polishing, and/or chemical mechanical polishing (CMP)), chemical thinning (e.g., wet etching, dry etching), laser thinning, acoustic thinning, or any combination thereof.

As illustrated in FIG. 4C, top channel structures 418 can be formed which extend through the top portion 416 of the second stack structure 120. The top channel structures 418 can have the same array layout, e.g., dimension, pitch, or quantity of channel structures, as the initial channel structures 406 such that each top channel structure 418 is formed on top of a respective initial channel structure 406. The top channel structure 418 can also include the layered structure 140. In some implementations, a top channel structure 418 and its respective initial channel structure 406 forms an integrated channel structure. The integrated channel structures in the first region 101 can be implemented as the first channel structure 110 in FIG. 1A. The integrated channel structures in the second region 103 and/or the third region 113 can be implemented as the dummy channel structure 111 in FIGS. 1A and 3A.

Although not shown, it is understood that the first channel structures 110 and/or the dummy channel structures 111 can be formed by etching trenches that extend through both the top portion 416 and bottom portion 414 of stack structures simultaneously. In other words, separate formation steps for the initial channel structures 406 and the top channel structures 418 are not required. In some implementations, the first channel structures 110 and/or the dummy channel structures 111 are created through multiple etching steps, with each step forming a segment of the trenches, e.g., the initial channel structures 406, and/or the top channel structures 418, along z direction. The aggregation of these trench segments, e.g., the initial channel structures 406, and/or the top channel structures 418, can result in the formation of the first channel structures 110 and the dummy channel structures 111.

As illustrated in FIG. 4D, which is the same as or substantially similar to FIG. 1A, the contact structures 150, 160 can be formed in the third region 113. The contact structures 150, 160 can be formed by etching the first dielectric layers 106 and the sacrificial layers 404 in the dielectric portion 107 of the third region 113 (see FIG. 3A). As a result, contact structures 150, 160 can extend into stack structure in the third region 113 and are surrounded by the first dielectric layers 106 and the sacrificial layers 404 in dielectric portion 107 of the third region 113. The contact structures 150, 160 can extend into the stack structure at different depths in the third region 113. The bottom of each contact structure 150, 160 can be aligned with a corresponding sacrificial layer, as opposed to first dielectric layer 106. As noted above, each contact structure 150, 160 can include a vertical contact 152 and an interconnect line 151. The interconnect line 151 can be in contact with the vertical contact 152 and a corresponding one of the first conductive layers 136 (see FIG. 3A). The formation of contact structures 150, 160 can include a plurality of processes including, but not limited to, photolithography, dry/wet etch, thin film deposition, thermal growth, implantation, chemical mechanical polishing (CMP), and any other suitable processes.

In the first region 101 and the second region 103, the sacrificial layers 404 can be replaced with a conductive material to form gate lines 136 in the bottom portion 414 of the stack structure 402 and the second conductive layers 138 in the top portion 416 of the stack structure 402, as illustrated in FIG. 4D. In the conductive portion 105 of the third region 113, the sacrificial layers 404 can also be replaced with the conductive material. In some implementations, the replacement of the sacrificial layers 404 in the conductive portion 105 of the third region 113 is performed simultaneously with the replacement of the sacrificial layers 404 in the first region 101 and the second region 103. In some implementations, the replacement of the sacrificial layers 404 in the conductive portion 105 of the third region 113 is accomplished at a separate process step from the replacement of the sacrificial layers 404 in the first region 101 and the second region 103.

In some implementations, sacrificial layers 404 can be removed by a wet etch and/or dry etch process. After the removal of sacrificial layers 404, a plurality of openings can be formed between adjacent first dielectric layers 106 and/or adjacent second dielectric layers 139. Then, a conductive material can be deposited into the openings to form conductive layers. The conductive layers can be the gate lines 136 in the bottom portion 414 of the stack structure 402 and the second conductive layers 138 in the top portion 416 of the stack structure 402. The gate lines 136 can be isolated from one another by the first dielectric layers 106. The second conductive layers 138 can be isolated from one another by the second dielectric layers 139. In some implementations, gate lines 136 and second conductive layers 138 are made of conductive materials including, but not limited to, W, Co, Cu, Al, polysilicon, doped silicon, silicides, or any combination thereof. In some implementations, the gate lines 136 and/or the second conductive layers 138 are formed by one or more thin film deposition processes including, but not limited to, CVD, PVD, ALD, MOCVD, MBE, sputtering, or any combination thereof.

One or more SG cut structure 126 can be formed which extend through at least one second conductive layers 138 in the top portion 416 of the stack structure 402 along the z-direction, as illustrated in FIG. 1B. The SG cut structures 126 can have an elongated shape with its length extending along the x-direction in the first region 101 and the second region 103, as illustrated in FIGS. 2A-2B. The SG cut structures 126 can be configured to separate at least one of the second conductive layer 138 in the top portion 416 of the stack structure 402 into SG lines 121 (FIGS. 2A-2B). In some implementations, the top portion 416 of the stack structure 402 includes one to ten layers of the second conductive layers 138. In some implementations, one of the SG cut structures 126 partially extends into one or more adjacent first channel structures 110, as illustrated in FIG. 1B. The sidewall surface 127 of the SG cut structure 126 can be in contact with the semiconductor channel layer 114 of the one or more adjacent first channel structures 110, as illustrated in FIG. 2A. In some implementations, as the SG cut structure 126 only partially extends into the first channel structure 110, the first channel structure 110 can still be functional channels in which memory cells are formed. Consequently, this memory device structure reduces the number of required dummy channel structures in the first region 101, allowing for an increased density of memory strings.

The bottom portion 414 of the stack structure 402 with gate lines 136 can be the first stack structure 104 in FIGS. 1A-2B. The top portion 416 of the stack structure 402 with SG lines 121 can be the second stack structure 120 in FIGS. 1A-2B. The first dielectric layers 106 in the top portion 416 of the stack structure 402 can be also referred as the second dielectric layer 139 in this disclosure.

In the dielectric portion 107 of the third region 113, the sacrificial layers 404 can be partially replaced with interconnect lines 151, 161 to form material layers 146. During this process, some portions, e.g., the first portion 302 as shown in FIG. 3B, of the sacrificial layers 404 remain intact in dielectric portion 107 of the third region 113. The replaced portion, e.g., the second portion 304 as shown in FIG. 3B, of the sacrificial layers 404 can form interconnect lines 151, 161 for electrical connection between vertical contact 152 of the contact structures 150, 160 and the corresponding first conductive layer 136 (gate line) or the corresponding SG lines 121. Thus, in some implementations, interconnect line 151, 161 is sandwiched between two first dielectric layers 106, as opposed to two sacrificial layers 404, in the dielectric portion 107 of the third region 113. The stack structure 402 in the third region 113 with replaced conductive materials in the conductive portion 105 and interconnect lines 151, 161 can form the third stack structure 170 in FIGS. 1A, 3A-3B and 4D.

The SG contact structures 130 can be formed in the second region 103 (staircase region 103). Each SG contact structure 130 can land on the landing surface 144 of the respective SG line 121, as illustrated in FIGS. 1A and 2A-2B. As noted above, each stair 132 can include a second conductive layer 138 which is separated into one or more SG lines 121 by the SG cut structures 126. The one or more SG lines 121 for each stair 132 can be arranged along y-direction. The landing surface 144 of each stair 132 can be the top surface of the second conductive layer 138 that is not covered by the preceding stair 132, as illustrated in FIG. 1A. The SG contact structure 130 can be formed by a plurality of processes including, but not limited to, photolithography, dry/wet etch, thin film deposition, thermal growth, implantation, chemical mechanical polishing (CMP), and any other suitable processes. The SG contact structure 130 can be made of materials including, but not limited to W, Co, Cu, Al, TiN, TaN, polysilicon, or any combination thereof.

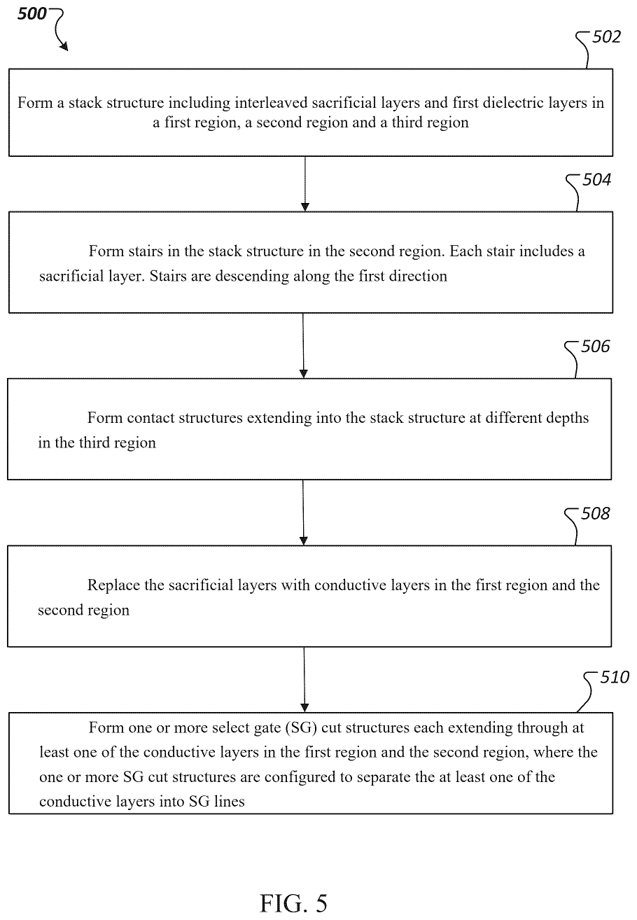

FIG. 5 is a flow chart for an example process 500 to form the example semiconductor device 100. At step 502, a stack structure is formed, which includes interleaved sacrificial layers and first dielectric layers in a first region, a second region and a third region. The stack structure can be, e.g., the stack structure 402 of FIGS. 4A-4C. The sacrificial layers can be, e.g., the sacrificial layers 404 of FIGS. 4A-4D. The first region can be, e.g., the first region 101 of FIGS. 1A-4D. The second region can be, e.g., the second region 103 of FIGS. 1A-4D. The third region can be, e.g., the third region 113 of FIGS. 1A-4D.

At step 504, a plurality of stairs in the stack structure are formed in the second region. Each of the plurality of stair includes a sacrificial layer of the sacrificial layers. The plurality of stairs descending along the first direction. The stairs can be, e.g., the initial stairs 406 of FIGS. 4A-4C. The first direction can be, e.g., the x direction in FIGS. 1A-2B and 4A-4D.

At step 506, contact structures are formed which extend into the stack structure at different depths in the third region. The contact structures can be, e.g., the contact structures 150, 160 in FIGS. 1A-1B, 3A-3B and 4D.

At step 508, the sacrificial layers are replaced with conductive layers in the first region and the second region. The conductive layers can be, the first conductive layers 136 (gates lines 136, or word lines 136) of FIGS. 1A-1B, 3A and 4D, and/or the second conductive layers 138 of FIGS. 1A-1B, 3A and 4D.

At step 510, one or more select gate (SG) cut structures are formed. Each SG cut structure extends through at least one of the conductive layers of the stack structure in the first region and the second region. The one or more SG cut structures are configured to separate the at least one of the conductive layers into SG lines. The SG cut structures can be, e.g., the SG cut structures 126 of FIGS. 1B-2B. The SG lines can be, e.g., the SG lines 121 of FIGS. 2A-2B. The at least one of the conductive layers can be, e.g., the second conductive layers 138 of FIGS. 1A-1B, 3A and 4D.

In some implementations, the process 500 includes forming a plurality of SG contact structures each in contact with a respective SG line of the SG lines at a respective stair of the plurality of stairs in the second region. The SG contact structures can be, e.g., the SG contact structures 130 of FIGS. 1A, 2A-2B and 4D.

In some implementations, the process 500 includes forming a plurality of first channel structures extending through the stack structure along a second direction in the first region. A plurality of dummy channel structures is also formed extending through the plurality of stairs along the second direction in the second region. The second direction being perpendicular to the first direction. The first channel structures can be, e.g., the first channels structures 110 of FIGS. 1A-2B and 4A-4D. The dummy channel structures can be, e.g., the dummy channel structures 111 of FIGS. 1A, 2A-3A and 4A-4D. The second direction can be, e.g., the z direction in FIGS. 1A-4D.

In some implementations, the process 500 includes replacing the sacrificial layers with the conductive layers in a conductive portion of the third region. The conductive portion of the third region can be, e.g., the conductive portion 105 of the third region 113.

In some implementations, forming the contact structures includes forming a first vertical contact in a dielectric portion of the third region. The dielectric portion and the conductive portion being arranged in a third direction. The third direction is perpendicular to the first direction. The first vertical contact can be, e.g., the first vertical contact 152, 162 of FIGS. 1A, 3A-3B, and 4D. The dielectric portion of the third region can be, e.g., the dielectric portion 107 of the third region 113 of FIGS. 1A, 3A-3B and 4D. The third direction can be, e.g., the y direction of FIG. 3A.

In some implementations, the process 500 includes replacing a part of a sacrificial layer of the sacrificial layers with an interconnect line in the dielectric portion of third region. The interconnect line is in contact with the first vertical contact and a corresponding one of the conductive layers. The interconnect line can be, e.g., the interconnect line 151 of FIGS. 1A, 3A-3B, and 4D.

In some implementations, the process 500 includes replacing a part of a sacrificial layer of the sacrificial layers with an interconnect line in the dielectric portion of third region. The interconnect line being in contact with the first vertical contact and a corresponding one of the SG lines. The interconnect line can be, e.g., the interconnect line 161 of FIGS. 1A, 3A-3B, and 4D.

In some implementations, one of the SG cut structures partially extends into at least one of the first channel structures. A sidewall surface of the SG cut structure is in contact with a semiconductor channel layer of the at least one of the first channel structures. The sidewall surface of the SG cut structure can be, e.g., the sidewall surface 127 of SG cut structure 126 of FIGS. 1B-2B. The semiconductor channel layer can be, e.g., the semiconductor channel layer 114 of FIGS. 1A-1B and 4A-4D.

In some implementations, forming the plurality of first channel structures includes forming a blocking layer, a charge trapping layer, a dielectric layer and a channel layer arranged radially in each of the plurality of first channel structures. The blocking layer can be, e.g., the blocking layer 122 of FIGS. 1A-1B and 4A-4D. The charge trapping layer can be, e.g., the charge trapping layer 118 of FIGS. 1A-1B and 4A-4D. The dielectric layer can be, e.g., the dielectric layer 116 of FIGS. 1A-1B and 4A-4D.

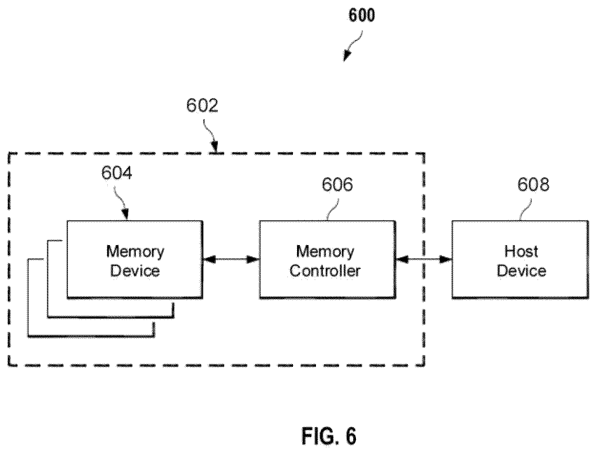

FIG. 6 illustrates a block diagram of a system 600 having one or more semiconductor devices (e.g., memory devices), according to one or more implementations of the present disclosure. The system 600 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 6, the system 600 can include a host device 608 and a memory system 602 having one or more 3D memory devices 604 and a memory controller 606. Host device 608 can include a processor of an electronic device, such as a central processing unit (CPU), or a system-on-chip (SoC), such as an application processor (AP). Host device 608 can be configured to send or receive data to or from the one or more 3D memory devices 604.

A 3D memory device 604 can be any 3D memory device disclosed herein, such as the 3D semiconductor device 100 of FIGS. 1A and 2A-2B, or a part of the 3D semiconductor device 100 of FIGS. 1B and 3A-3B, or a structure at an intermediate fabrication process of the 3D semiconductor device 100 of FIGS. 4A-4C.

In some implementations, a 3D memory device 604 includes a NAND Flash memory. Memory controller 606 (a.k.a., a controller circuit) is coupled to 3D memory device 604 and host device 608. Consistent with implementations of the present disclosure, 3D memory device 604 can include a plurality of conductive interconnections through a cover layer that are in contact with conductive pads in a conductive pad layer, and memory controller 606 can be coupled to 3D memory device 604 through at least one of the plurality of conductive interconnections. Memory controller 606 is configured to control 3D memory device 604. For example, memory controller 606 can be configured to operate a plurality of channel structures via word lines 136. Memory controller 606 can manage data stored in 3D memory device 604 and communicate with host device 608.

In some implementations, memory controller 606 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 606 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 606 can be configured to control operations of 3D memory device 604, such as read, erase, and program (or write) operations. Memory controller 606 can also be configured to manage various functions with respect to the data stored or to be stored in 3D memory device 604 including, but not limited to bad-block management, garbage collection, logical-to-physical address conversion, wear leveling, etc. In some implementations, memory controller 606 is further configured to process error correction codes (ECCs) with respect to the data read from or written to 3D memory device 604. Any other suitable functions can be performed by memory controller 606 as well, for example, formatting 3D memory device 604.

Memory controller 606 can communicate with an external device (e.g., host device 608) according to a particular communication protocol. For example, memory controller 606 can communicate with the external device through at least one of various interface protocols, such as a USB protocol, an MMC protocol, a peripheral component interconnection (PCI) protocol, a PCI express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 606 and one or more 3D memory devices 604 can be integrated into various types of storage devices, for example, be included in the same package, such as a universal Flash storage (UFS) package or an eMMC package. That is, memory system 602 can be implemented and packaged into different types of end electronic products. In one example as shown in FIG. 6, memory controller 606 and a single 3D memory device 604 can be integrated into a memory card 602. Memory card 602 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier can be a tangible non-transitory computer storage medium. Alternatively, or in addition, the carrier can be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some embodiments,” “some implementations,” “one implementation,” “an implementation,” “an example implementation,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and can, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−. 10%, .+−. 20%, or .+−. 30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows can include implementations in which the first and second features can be in direct contact, and can also include implementations in which additional features can be formed between the first and second features, such that the first and second features can not be in direct contact. In addition, the present disclosure can repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that can be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features can be described above as acting in certain combinations and even initially be claimed as such, one or more features from a claimed combination can in some cases be excised from the combination, and the claim can be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing can be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing can be advantageous.

The breadth and scope of the present disclosure should not be limited by any of the above-described exemplary implementations, but should be defined only in accordance with the following claims and their equivalents.

What is claimed is:

1. A semiconductor device, comprising:
a first stack structure comprising first conductive layers extending in a first region and a second region;
a second stack structure over the first stack structure along a first direction, the second stack structure comprising interleaved second conductive layers and dielectric layers extending in the first region and the second region, the second stack structure comprising a plurality of stairs in the second region, each of the plurality of stairs comprising a landing surface; and
a third stack structure in a third region, a top surface of the third stack structure being at a level above the landing surface of an adjacent stair of the plurality of stairs along the first direction.

2. The semiconductor device of claim 1, further comprising a plurality of contact structures in the third region, wherein the plurality of contact structures extend into the third stack structure at different depths, and wherein a first contact structure of the plurality of contact structures comprises a first vertical contact and a first interconnect line, the first interconnect line being in contact with the first vertical contact and a corresponding one of the first conductive layers.

3. The semiconductor device of claim 1, wherein edges of the second conductive layers and the dielectric layers in the second region are configured to define the plurality of stairs.

4. The semiconductor device of claim 2, further comprising first channel structures extending through the first stack structure and the second stack structure along the first direction in the first region.

5. The semiconductor device of claim 4, further comprising:
a plurality of select gate (SG) cut structures each extending through the second stack structure along a second direction, the second direction being perpendicular to the first direction, the SG cut structures configured to separate each of the second conductive layers into a plurality of SG lines; and
a plurality of SG contact structures each in contact with a respective SG line of the plurality of SG lines at a respective stair of the plurality of stairs in the second region.

6. The semiconductor device of claim 1, wherein the second region is between the first region and the third region along a second direction, the second direction being perpendicular to the first direction.

7. The semiconductor device of claim 5, wherein a SG cut structure of the SG cut structures partially extends into at least one of the first channel structures, and a sidewall surface of the SG cut structure is in contact with a semiconductor channel layer of the at least one of the first channel structures.

8. The semiconductor device of claim 1, wherein the third region comprises a dielectric portion and a conductive portion, the dielectric portion and the conductive portion being arranged in a third direction, the third direction being perpendicular to the first direction, wherein the first conductive layers further extend in the conductive portion of the third region.

9. The semiconductor device of claim 5, wherein a SG line of the plurality of SG lines extends in the third region, and wherein a second contact structure of the plurality of contact structures comprises a second vertical contact and a second interconnect line, the second interconnect line being in contact with the second vertical contact and the SG line.

10. The semiconductor device of claim 5, wherein the first conductive layers and the SG lines comprise tungsten (W).

11. A method, comprising:
forming a stack structure comprising interleaved sacrificial layers and first dielectric layers in a first region, a second region and a third region;
forming a plurality of stairs in the stack structure in the second region, each of the plurality of stair comprising a sacrificial layer of the sacrificial layers, the plurality of stairs descending along a first direction;
forming contact structures extending into the stack structure at different depths in the third region;
replacing the sacrificial layers with conductive layers in the first region and the second region; and
forming one or more select gate (SG) cut structures each extending through at least one of the conductive layers in the first region and the second region, wherein the one or more SG cut structures are configured to separate the at least one of the conductive layers into SG lines.

12. The method of claim 11, comprising: forming a plurality of SG contact structures each in contact with a respective SG line of the SG lines at a respective stair of the plurality of stairs in the second region.

13. The method of claim 11, comprising: forming a plurality of first channel structures extending through the stack structure along a second direction in the first region, and a plurality of dummy channel structures extending through the plurality of stairs along the second direction in the second region, the second direction being perpendicular to the first direction.

14. The method of claim 11, comprising replacing the sacrificial layers with the conductive layers in a conductive portion of the third region.

15. The method of claim 14, wherein forming the contact structures comprises forming a first vertical contact in a dielectric portion of the third region, the dielectric portion and the conductive portion being arranged in a third direction, the third direction being perpendicular to the first direction.

16. The method of claim 15, comprising replacing a part of a sacrificial layer of the sacrificial layers with an interconnect line in the dielectric portion of the third region, the interconnect line being in contact with the first vertical contact and a corresponding one of the conductive layers.

17. The method of claim 15, comprising replacing a part of a sacrificial layer of the sacrificial layers with an interconnect line in the dielectric portion of the third region, the interconnect line being in contact with the first vertical contact and a corresponding one of the SG lines.

18. The method of claim 13, wherein one of the one or more SG cut structures partially extends into at least one of the first channel structures, and a sidewall surface of the SG cut structure is in contact with a semiconductor channel layer of the at least one of the first channel structures.

19. The method of claim 13, wherein forming the plurality of first channel structures comprising forming a blocking layer, a charge trapping layer, a dielectric layer and a channel layer arranged radially in each of the plurality of first channel structures.

20. A system, comprising:
a memory device configured to store data, the memory device comprising:
a first stack structure comprising first conductive layers extending in a first region and a second region;
a second stack structure over the first stack structure along a first direction, the second stack structure comprising interleaved second conductive layers and dielectric layers extending in the first region and the second region, the second stack structure comprising a plurality of stairs in the second region, each of the plurality of stairs comprising a landing surface; and
a third stack structure in a third region, a top surface of the third stack structure being at a level above the landing surface of an adjacent stair of the plurality of stairs along the first direction; and
a memory controller electrically connected to the memory device and configured to operate the memory device.
